(19) United States
(12) Patent Application Publication
(10) Pub. No.: US 2007/0108517 A1
(43) Pub. Date: May 17, 2007

(54) LDMOS with independently biased source

(75) Inventors: You-Kuo Wu, Sijhih City (TW); Fu-Hsin Chen, Hsinchu County (TW); P.Y. Chiang, Su-ao Township (TW); An-Min Chiang, Hsinchu City (TW)

Correspondence Address: Howard Chen, Esq.;Preston Gates & Ellis LLP, Suite 1700, 55 Second Street, San Francisco, CA, 94105, US

(73) Assignee: Taiwan Semiconductor Manufacturing Co., Ltd.

(21) Appl. No.: 11/273,222

(22) Filed: Nov. 12, 2005

(51) Int. Cl. H01L 29/76

(52) U.S. Cl. 257/335

(57) ABSTRACT

A power metal-oxide semiconductor device provides an P-type base region that includes the N+ device source and is biased differently than the P-type substrate by application of an electrical load. In one embodiment, an LDMOS device with a NPN configuration is used but the coupling of the device source to the base contact prevents the NPN parasitic device from operating. The P-type base is formed in an N-well that separates the base from the P-type substrate and surrounding P-wells. Vertical punch-through is prevented by a high-impurity N+ buried layer that separates the N-well from the P-type substrate.

### BACKGROUND

The present invention relates generally to semiconductor devices, and more particularly to a structure for allowing a bias in the base region and for limiting vertical punch-through in power metal-oxide semiconductor devices.

A conventional lateral double-diffused metal-oxide-semiconductor (LDMOS) device, typically a power MOS, can provide reduced “on state” resistance in a circuit. Therefore, such a device is very suitable to be used in the output stage of any power management circuits because of its inherently lower RC time delay.

A conventional LDMOS structure typically includes a very narrow channel length, which in turn in decided by a smaller P-type base region inside a P-well, with the smaller P-type base region defined by the location of a self-aligned gate of the device, one or more field oxide implants and other resurf structures. To prevent parasitic bipolar junction transistor (BJT) from turning on, and to prevent from having a body effect, the P-type base region pick-up and the source pick-up are typically butted contacts.

Some power management applications require the source side to be loaded. In other words, the source may need to have a bias within device operation rage. Unfortunately, in conventional designs, the P-well which encloses the P-type base region is typically connected to a P-type substrate, thereby essentially shorting the P-type base region to the P-type substrate. Since the P-type substrate is typically grounded, it is impossible to provide the source, which is connected to the P-type base region, with any other bias.

Other power management applications require more protection from punch-through. Unfortunately, in conventional designs, the N-well depth is limited by the thermal budget in processing. Since the N-well depth is typically limited, vertical punch-through between the P-type base region and the P-type substrate occurs rather frequently and easily. This punch-through may disable completely the LDMOS device and further may stall one or more circuit operations.

Therefore, desirable in the art of LDMOS device designs are improved structures for allowing a bias in the base region and for limiting vertical punch-through in power metal-oxide semiconductor devices.

### SUMMARY

In view of the foregoing, the following provides an improved structure for allowing a bias in the base region and for limiting vertical punch-through in power metal-oxide semiconductor devices.

In one embodiment, a lateral double-diffused metal-oxide-semiconductor device of a NPN configuration comprises a semiconductor substrate of a first type and a first well of the first type that extends downward from the surface of the semiconductor substrate. A second well of a second type is enclosed subjacently by the semiconductor substrate and laterally by the first well. The device drain is formed in the second well. A dielectric is formed over the second well, and a conductor formed over the dielectric to form a device gate. A base region of the first type is formed in the second well and separated from the first well by a predetermined separation. The device source is disposed in the base region, and preferably electrically coupled to a first contact of the base region for ensuring that the parasitic equivalent is not turned on. For the NPN configuration, the first type is P-type and the second type is N-type. In an exemplary embodiment, an N+ buried layer may be advantageously formed between the second well and the semiconductor substrate for preventing or at least limiting punch-through. The invention also provides for the formation and biasing of the LDMOS.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 illustrates a conventional LDMOS.

FIG. 2 illustrates a LDMOS in accordance with the first embodiment of the present invention.

FIG. 3 illustrates a LDMOS with a resurf structure in accordance with the second embodiment of the present invention.

### DESCRIPTION

The following provides a detailed description of an improved structure for allowing a bias in the base region and for limiting vertical punch-through in power metal-oxide semiconductor devices.

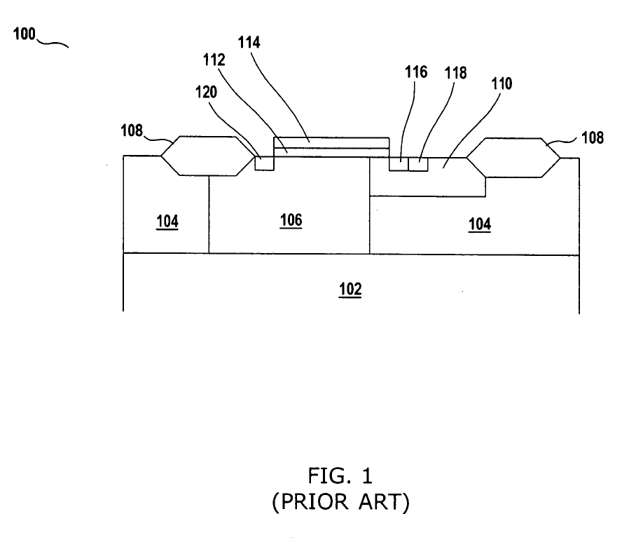

FIG. 1 illustrates a conventional lateral double-diffused metal-oxide-semiconductor (LDMOS) 100. The conventional LDMOS 100 may provide reduced “on state” resistance in a circuit, including a high voltage application, but it is typically not amenable to be deployed in a circuit that requires the insertion of a circuit load between the source and the electrical ground. As shown, the LDMOS 100 has both the source and the drain on the same active surface of a semiconductor substrate 102, which is of P-type. A P-well 104 extends downward from the active surface of the semiconductor substrate 102. A N-well 106 is enclosed and isolated by the semiconductor substrate 102, and the P-well 104. Surface structures are further electrically isolated by a ring of field oxides (FOXs) 108. A base region 110, which is of P-type, is diffused into the inner edge of the P-well 104, and is extended slightly into the N-well 106. A gate oxide 112 and a gate conductor 114 are constructed on top of partially the N-well 106 and the base region 110 to bridge from within the base region 110 to the channel length within the N-well 106. It is understood that the gate conductor 114 is typically polycrystalline silicon (poly). A N+ source 116 is diffused into the base region 110 and adjacent to the end of the gate conductor 114. On the opposite side of the N+ source 116 is a P+ contact 118, which is diffused to make electrical contact to the base region 110. A N+ drain 120 is diffused into the N-well 106 and adjacent to the opposite end of the gate conductor 114. Later in the process, the N+ source 116 and the P+ contact 118 are shorted together by a metal pattern, not shown. In an exemplary embodiment, a butted contact may be filled with metal and used to couple the N+ source 116 and the P+ contact 118. As shown, the base drive of the parasitic transistor is held to zero by the electrical short between the N+ source 116, which can be alternatively seen as the parasitic bipolar emitter, and the base region 110. This insures that the parasitic NPN transistor cannot become active. It is understood that the prevented parasitic lateral bipolar NPN transistor is composed of the N+ source 116 as its bipolar emitter, the base region 110 as its bipolar base, and the N+ drain 120 as its bipolar collector.

It should be understood that the “+” designation signifies a high level of dopant impurity concentration as known in the art. For example a P+ region is a P-type region with a high concentration of holes and areas designated P+ will generally have a higher dopant concentration than those simply designated as P-type.

The N+ source 116 is shorted to the P+ contact 118 for contact to the base region 110. It is understood that the base region 110 is contiguous with the P-well 104, which is contiguous with the semiconductor substrate 102. In other words, since the base region 110 cannot be electrically separated from the semiconductor substrate 102, it is nearly impossible to form any circuit that utilizes a source load, or any non-zero source bias.

The present invention offers an improved structure that allows the insertion of a load between the N+ source 116 and ground.

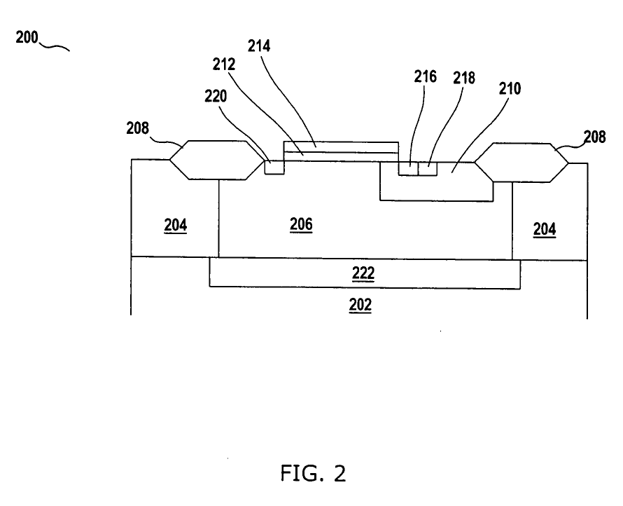

FIG. 2 illustrates a LDMOS 200 in accordance with the first embodiment of the present invention. As shown, the LDMOS 200 has both its source and its drain on the same active surface of a semiconductor substrate 202, which is of P-type. A P-well 204 extends downward from the active surface of the semiconductor substrate 202. A N-well 206 is enclosed and isolated by the semiconductor substrate 202 and the P-well 204. In an exemplary embodiment, N-well 206 is laterally surrounded by P-well 204 and subjacently enclosed by semiconductor substrate 202. Surface structures are further electrically isolated by a ring of FOXs 208.

A base region 210, which is P-type, is diffused into the N-well 206, with a predetermined lateral separation from the P-well 204. The base region 210 may be formed using a self-aligned gate and one or more field oxide implants. As shown, the base region 210 is physically and electrically separated from the semiconductor substrate 202, thereby allowing it to be biased differently from the semiconductor substrate 202. Now, it is possible to insert, or apply, an electrical load between the base region 210 and the electrical ground, which is connected to the semiconductor substrate 202. As such, the source (N+ source 216) of the LDMOS 200 can be biased independently from the grounded substrate.

A gate oxide 212 and a gate conductor 214 are constructed on the active surface of the semiconductor substrate 202 to bridge from within the base region 210 to a MOS channel length within the N-well 206. It is understood that the gate conductor 214 is typically poly and forms a gate electrode. A N+ source 216 is diffused into the base region 210, adjacent to the end of the gate conductor 214. P+ contact 218 is disposed on the opposite side of the N+ source 216, from the gate conductor 214. P+ contact 218 is diffused to make electrical contact to the base region 210. A N+ drain 220 is diffused into the N-well 206, adjacent to the opposite end of the gate conductor 214. The N+ source 216 and the P+ contact 218 are advantageously shorted together by a patterned metal wire, not shown. In an exemplary embodiment, a butted contact may be filled with metal and used to couple the N+ source 216 and the P+ contact 218. Conventional methods may be used to form the butted contact. In this embodiment, the base drive of a parasitic NPN transistor is held to zero by the electrical short between the N+ source 216, which can be seen as the parasitic bipolar emitter, and the base region 210. This insures that the parasitic NPN transistor cannot become active. The parasitic lateral bipolar NPN transistor, that is now prevented, is composed of the N+ source 216 as its bipolar emitter, the base region 210 as its bipolar base, and the N+ drain 220 as its bipolar collector. Unless otherwise noted, the doped wells an other impurity areas may be formed by conventional implantation and or diffusion methods.

The present invention obviates a potential hazard with the new structure. The reasonable depth of N-well 206 is limited and governed by the thermal budget of the total process. In addition to the problem of the parasitic lateral bipolar transistor addressed by the invention, there is the potential problem of vertical punch-through from the base region 210 to the semiconductor substrate 202. In normal operation, voltage reverse biases the junction between the base region 210 and the N-well 206. That depletion region can easily extend to the junction between the N-well 206 and the semiconductor substrate 202. That is punch-through, which allows too much current flow and is likely to cause latch-up, a condition in which current cannot be turned off by normal functional means. The present invention prevents this condition by optionally inserting a N+ buried layer 222 between the N-well 206 and the substrate 202. If the depletion region extends to the N+ buried layer 222, the growth of the depletion region is severely slowed since the required accumulation of compensating current carriers is swift from the heavily doped N+ buried layer 222. Therefore, the depletion region expansion no longer reaches the semiconductor substrate 202, thereby preventing or at least limiting punch-through.

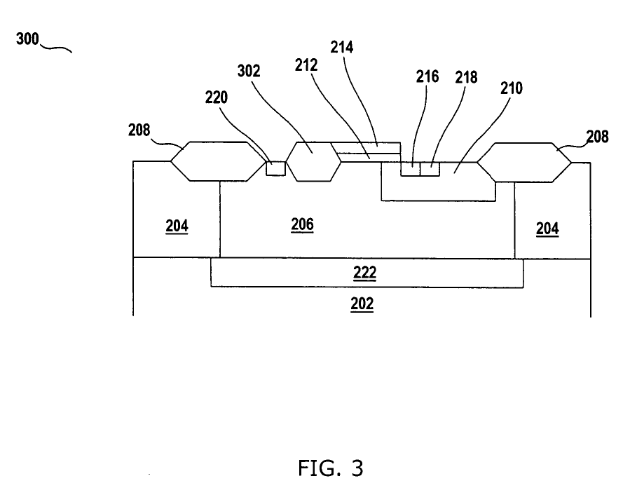

FIG. 3 illustrates a LDMOS 300 with a resurf structure in accordance with the second embodiment of the present invention. The LDMOS 300 is essentially the same as the LDMOS 200, except that an additional FOX 302 pattern is present between the N+ drain 220 and the gate conductor 214 is added. The FOX 302, to be seen as a lateral separator, provides an additional distance over which a high voltage depletion width is spaced.

It is understood that all isolations, shown as local or field oxide, can be shallow trench isolations (STI). These structures can be merged into other process technologies, such as low voltage mixed-mode processes, low voltage logic, and high voltage processes. In various exemplary embodiments, the drain may be multi-diffused, i.e., formed using multiple diffusion operations.

The above illustration provides many different embodiments or embodiments for implementing different features of the invention. Specific embodiments of components and processes are described to help clarify the invention. These are, of course, merely embodiments and are not intended to limit the invention from that described in the claims.

Although the invention is illustrated and described herein as embodied in one or more specific examples, it is nevertheless not intended to be limited to the details shown, since various modifications and structural changes may be made therein without departing from the spirit of the invention and within the scope and range of equivalents of the claims. Accordingly, it is appropriate that the appended claims be construed broadly and in a manner consistent with the scope of the invention, as set forth in the following claims.

What is claimed is:

1. A power metal-oxide-semiconductor device comprising:
a semiconductor substrate of a first type;
a first well of the first type extending downwardly from a surface of the semiconductor substrate;
a second well of a second type laterally surrounded by the first well and subjacently enclosed by the semiconductor substrate;
a device drain formed within the second well;
a gate dielectric formed over the second well and a gate electrode formed on the gate dielectric thereby forming a device gate;
a base region of the first type formed in the second well and separated from the first well and the semiconductor substrate; and
a device source disposed in the base region and electrically coupled to a first contact for contacting the base region.

2. The device of claim 1, wherein the first type is P-type and the second type is N-type.

3. The device of claim 2, wherein the first contact is P+ type.

4. The device of claim 2, wherein the device source and the device drain are both N+ type.

5. The device of claim 1, wherein the gate dielectric is formed over the second well and the base region.

6. The device of claim 1, wherein the device source being electrically coupled to the first contact prevents activation of a parasitic bipolar junction transistor.

7. The device of claim 1, wherein the base region and the semiconductor substrate have different electrical biases.

8. The device of claim 7, wherein the semiconductor substrate is biased at ground voltage and the base region is biased at a non-zero bias voltage different from ground voltage.

9. The device of claim 1, wherein the device source and the device drain are both of the second type.

10. The device of claim 1, wherein the gate dielectric is an oxide and the gate electrode is polycrystalline silicon.

11. The device of claim 1, wherein the device source is adjacent one end of the device gate and the device drain is adjacent an opposed end of the device gate.

12. The device of claim 1, wherein the device source and the first contact are electrically coupled by metal disposed in a butted contact thereby holding a base drive of a parasitic equivalent transistor device to zero.

13. The device of claim 1 further comprising a buried layer of the second type interposed between the second well and the semiconductor substrate, the buried layer including a higher dopant impurity concentration than the second well.

14. The device of claim 13 wherein the buried layer is sized and located to prevent a depletion region formed at a junction of the second well and the base region from extending to the semiconductor substrate.

15. The device of claim 13 wherein the buried layer is sized and located to prevent punch-through between the base region and the semiconductor substrate.

16. The device of claim 1 further comprising at least one insulating feature disposed between the device drain and the device gate.

17. The device of claim 16 wherein the insulating feature is one of a field oxide formed on the surface and a shallow trench isolation feature extending downwardly from the surface.

18. A power metal-oxide-semiconductor device comprising:
a P-type semiconductor substrate;
at least one P-well extended downward from a surface of the semiconductor substrate;
a N-well laterally surrounded by the at least one P-well and subjacently enclosed by the semiconductor substrate;
an N-type device drain formed within the N-well;
a gate structure formed on the N-well and including a gate electrode formed over a gate oxide layer;
a P-type base region disposed within the N-well and separated from the P-well and the semiconductor substrate;
an N-type device source formed in the P-type base region and a P+ contact formed in the base region; and
an N+ buried layer interposed between the N-well and the semiconductor substrate, the N+ buried layer sized and located to prevent a depletion region formed at a junction of the N-well and the P-type base region, from extending to the semiconductor substrate.

19. The device of claim 18 wherein the device source is electrically coupled to the P+ contact.
